(19) United States
(12) Patent Application Publication
(10) Pub. No.: US 2008/0099884 A1
(43) Pub. Date: May 1, 2008

(54) Staggered guard ring structure

(76) Inventor: Masahio Inohara, Fujisawa (JP)

Correspondence Address: SPRINKLE IP LAW GROUP, 1301 W. 25TH STREET, SUITE 408, AUSTIN, TX, 78705, US

(21) Appl. No.: 11/590,266

(22) Filed: Oct. 31, 2006

(51) Int. Cl. H01L 23/52

(52) U.S. Cl. 257/620; 257/758

(57) ABSTRACT

Embodiments of the present invention provide staggered guard ring structures for stopping cracks from propagating during a dicing operation or by suffering mechanical stress after packaging. In one embodiment, a guard ring structure may comprise staggered metal bars, each of which extends into the ILD underneath it. In one embodiment, the extended portion of a metal bar may overlap a portion of another metal bar underneath it. In one embodiment, the bottom portion of a metal bar extends into the underlying substrate. In all embodiments of the invention, the metal-metal interfaces and the ILD-ILD interfaces do not lie on the same plane, effectively stopping cracks from propagating into the active circuit area through delaminated interfaces.

### FIELD OF THE INVENTION

This invention relates generally to crack stop structures. More particularly, embodiments of the present invention relate to staggered guard ring structures and methods of making the same.

### BACKGROUND OF THE INVENTION

Integrated circuit (IC) chips can be fabricated on a wafer and separated into individual chips by way of a dicing operation. During the dicing operation, cracks may develop and propagate from the dicing area. Such cracks may be caused by chips and/or cracks formed along edges of the IC chips during the dicing operation. Crack stop structures are useful in preventing the cracks from propagating into the active circuit area of the IC chips. A crack stop structure can be formed as a metal stack separating the dicing area from where the active circuitry of a chip resides.

FIG. 1 schematically depicts one example of a conventional crack stop structure, which can be seen as a metal interconnect structure 130 comprising a stack of metal bars. Each metal bar (e.g., metal bar 103) can be seen as a combination of a via and a wire. These metal bars are particularly arranged and aligned so that they are stacked on top of one another vertically in a linear fashion. These metal bars can be formed using a dual inlaid technique known as the dual damascene process in which conductive metal lines (e.g., copper) inlaid into an oxide or low dielectric constant (k) nonconductive layer (e.g., dielectric 102). Copper and inter-layer dielectric (ILD) interconnects thus formed can be used in manufacturing semiconductor devices (e.g., logic devices and direct random access memory (DRAM) devices, etc.). The number of ILDs may vary depending upon the type of device to be made. In the example shown in FIG. 1, five ILDs (at Layer 1 . . . 5) are formed on top of a silicon (Si) substrate (e.g., substrate 101) of an IC chip 100.

In conventional crack stop structures, interfaces between ILDs reside at the same plane as the interfaces between metal layers. For example, in FIG. 1, it can be seen that an ILD-ILD interface 110 resides at the same plane as a metal-metal interface 120 between Layer 4 and Layer 5. One weakness of this conventional crack stop structure is that cracks propagating through ILD-ILD interface 110 can easily delaminate metal-metal interface 120, causing crack stop structure 130 to fail to stop cracks from coming into the active circuit area inside of chip 100.

FIG. 2 schematically depicts another example of a conventional crack stop structure 230. Crack stop structure 230 is similar to crack stop structure 130 of FIG. 1, except that the metal bars have a different configuration. More specifically, these metal bars may have different dimensions (e.g., shape, width, length, depth, etc.) at the via level than at the wire level.

All metal bars, however, are aligned and stacked on top of one another vertically in a linear fashion. As an example, via bar 205 of Layer 5 lands on a wider trench bar 204 of Layer 4 and creates a metal-metal interface 220 that is at the same plane as an ILD-ILD interface 210.

Consequently, this conventional crack stop structure also suffers from the aforementioned weakness in that cracks propagating through ILD-ILD interface 210 can easily delaminate metal-metal interface 220, causing the crack stop structure 230 to fail to stop cracks from coming into the active circuit area of chip 200.

FIG. 1 and FIG. 2 exemplify that, in conventional metal stack crack stop structures, all vias and wires are aligned and stacked vertically in a linear fashion and each via lands on, but not into, a wire. What is more, interfaces between interlayer dielectrics reside at the same plane as the interfaces between metals. This planar relationship between two different types of interfaces can cause the metal layers to delaminate undesirably. A need exists for new crack stop structures that can effectively stop cracks from propagating during a dicing operation without the aforementioned weakness. Embodiments of the present invention can address this need and more.

### SUMMARY OF THE INVENTION

Embodiments of the present invention provide a staggered guard ring structure for stopping cracks from propagating during a dicing operation or by suffering mechanical stress after packaging.

In some embodiments, the guard ring structure comprises staggered metal bars that overlap horizontally.

In some embodiments, the guard ring structure comprises staggered metal bars that overlap horizontally but do not overlap vertically.

In some embodiments, the guard ring structure comprises staggered metal bars that overlap horizontally as well as vertically.

In some embodiments, the guard ring structure comprises staggered metal bars, each of which extends into a non-conducting material underneath it.

In some embodiments, the guard ring structure comprises staggered metal bars, each of which has an extended via bar formed into a portion of an inter-layer dielectric underneath it and a portion of a metal underneath it.

In some embodiments, the guard ring structure comprises staggered metal bars, one of which is extended into a substrate.

In all embodiments of the invention, the ILD-ILD interfaces and the metal-metal interfaces do not lie in a single geometric plane. No planar relationship therefore exists between the metal-metal interfaces and the ILD-ILD interfaces. By breaking the continuity between the two types of interfaces, embodiments of the invention can prevent the metal layers from delaminating and effectively stop cracks from propagating into the active circuit area of a chip, thereby overcoming the aforementioned weakness in conventional crack stop structures.

Other objects and advantages of the present invention will become apparent to one skilled in the art upon reading and understanding the detailed description of the preferred embodiments described herein with reference to the following drawings.

### BRIEF DESCRIPTION OF THE DRAWINGS

A more complete understanding of the present invention and the advantages thereof may be acquired by referring to the following description, taken in conjunction with the accompanying drawings in which like reference numbers indicate like features and wherein:

FIG. 1 is a cross sectional view of a conventional crack stop structure.

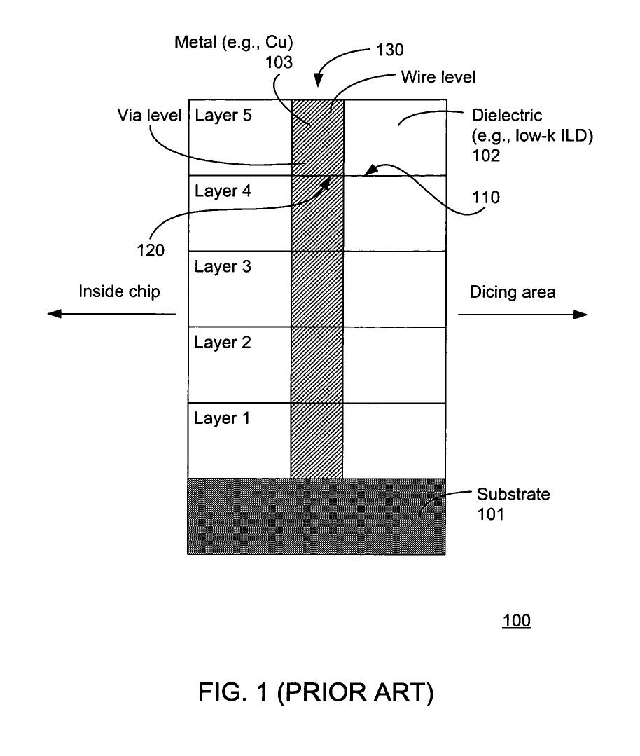

FIG. 2 is a cross sectional view of another conventional crack stop structure.

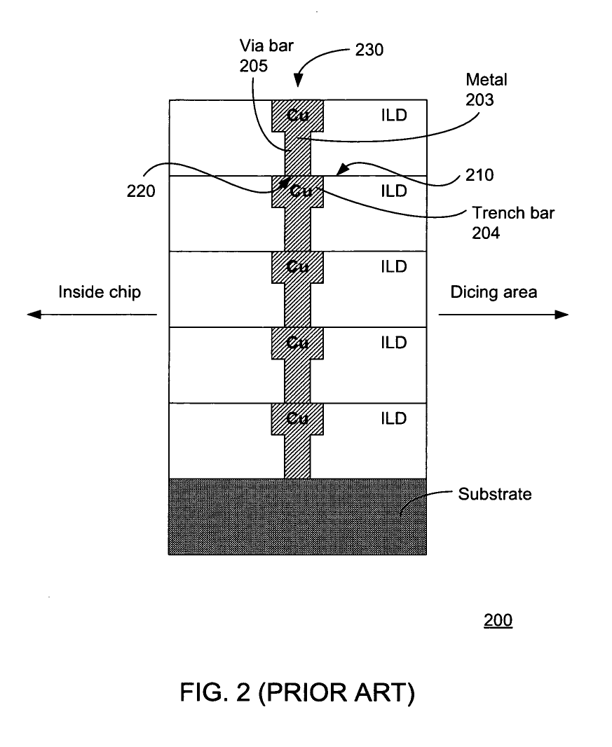

FIG. 3 is a cross sectional view of a schematic representation of a staggered guard ring structure according to one embodiment of the invention. The staggered guard ring structure comprises metal bars that overlap horizontally but not vertically.

FIG. 4 is a cross sectional view of a schematic representation of a staggered guard ring structure according to another embodiment of the invention. The staggered guard ring structure is similar to the one shown in FIG. 3 and comprises metal bars in a different configuration.

FIG. 5 is a cross sectional view of a schematic representation of a staggered guard ring structure according to one embodiment of the invention. The staggered guard ring structure comprises metal bars that overlap horizontally as well as vertically.

FIG. 6 is a cross sectional view of a schematic representation of a staggered guard ring structure according to another embodiment of the invention. The staggered guard ring structure is similar to the one shown in FIG. 5 and comprises metal bars in a different configuration.

FIG. 7 is a cross sectional view of a schematic representation of a staggered guard ring structure according to one embodiment of the invention. The staggered guard ring structure comprises metal bars that overlap horizontally but not vertically. One of the metal bars extends into the underlying substrate.

FIG. 8 is a cross sectional view of a schematic representation of a staggered guard ring structure, according to yet another embodiment of the invention. The staggered guard ring structure is similar to the one shown in FIG. 7, with one of the metal bars extending into the underlying substrate.

FIG. 9 is a cross sectional view of a schematic representation of a staggered guard ring structure according to another embodiment of the invention. The staggered guard ring structure comprises metal bars that overlap horizontally as well as vertically. One of the metal bars extends into the underlying substrate.

FIG. 10 is a cross sectional view of a schematic representation of a staggered guard ring structure, according to yet another embodiment of the invention. The staggered guard ring structure is similar to the one shown in FIG. 9, with one of the metal bars extending into the underlying substrate.

### DETAILED DESCRIPTION

The present invention and various features and advantageous details thereof will now be described with reference to the exemplary, and therefore non-limiting, embodiments that are illustrated in the accompanying drawings. Descriptions of known techniques and technologies may be omitted so as not to unnecessarily obscure the invention in detail. It should be understood, however, that the detailed description and the specific examples, while indicating preferred embodiments of the invention, are given by way of illustration only and not by way of limitation. Various substitutions, modifications, additions and/or rearrangements within the spirit and/or scope of the underlying inventive concept will become apparent to those skilled in the art from this disclosure.

Embodiments of the present invention provide a staggered guard ring structure for stopping cracks from propagating during a dicing operation or by suffering mechanical stress after packaging.

The guard ring structure comprises staggered metal bars arranged to have ILD-ILD interfaces and metal-metal interfaces lie in different geometric planes, effectively stopping cracks from propagating from the dicing area into the active circuit area of a chip during a dicing operation or by suffering mechanical stress after packaging.

In embodiments of the invention, as long as these two different types of inter-layer interfaces do not have a planar relationship, the guard ring structure can have various configurations. Some of the examples of the embodiments are shown in the following figures. The figures are not drawn to scale.

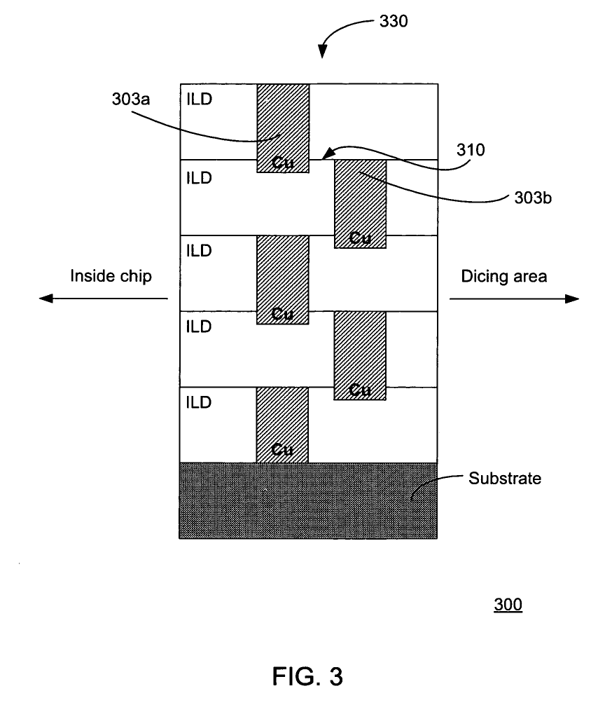

FIG. 3 is a cross sectional view of a schematic representation of a staggered guard ring structure according to one embodiment of the invention. In one embodiment, a staggered guard ring structure 330 comprises metal bars that are arranged or positioned in a staggered (i.e., alternating or zigzagging) pattern, with a portion of one metal bar (e.g., metal bar 303a) overlapping a portion of another metal bar (e.g., metal bar 303b) horizontally but not vertically.

In this embodiment, the metal bars of staggered guard ring structure 330 have no contact with each other and there are no metal-metal interfaces. As exemplified in FIG. 3, each metal bar digs or otherwise extends into an ILD underneath it. In this way, staggered guard ring structure 330 can effectively stop cracks from propagating from the dicing area through interfaces between layers (e.g., interface 310), thereby protecting the active circuit inside of chip 300. Staggered metal bars of guard ring structure 330 can be copper (Cu) formed into ILDs using a dual inlaid technique in a manner known to those skilled in the art.

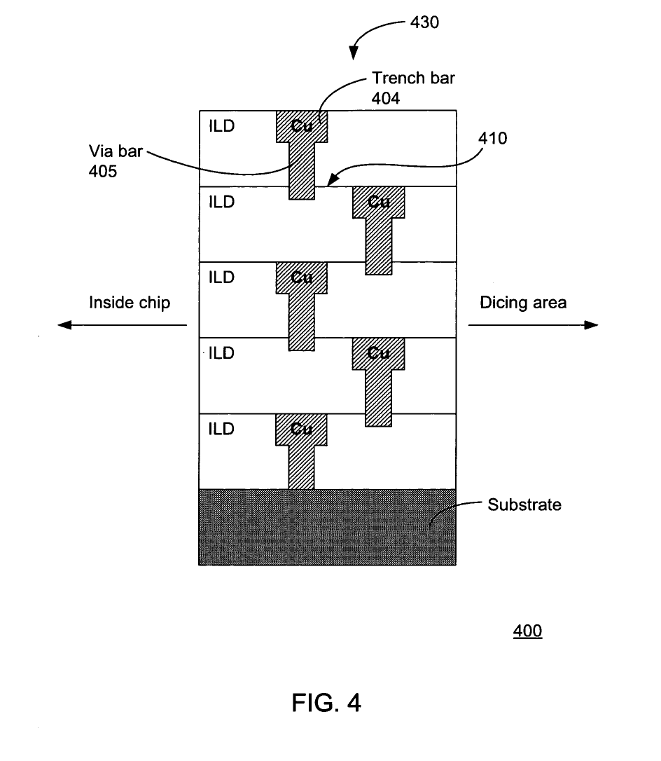

FIG. 4 is a cross sectional view of a schematic representation of a staggered guard ring structure according to another embodiment of the invention. Chip 400 has a staggered guard ring structure 430 that is similar to staggered guard ring structure 330 of FIG. 3 in that there are no metal-metal interfaces. The metal bars are arranged in an alternating or zigzagging fashion, with a portion of one metal bar overlapping a portion of another metal bar horizontally but not vertically. Each metal bar is a combination of a via (e.g., via bar 405) and a wire (e.g., trench bar 404). The vias and the wires differ in shape and size. Each elongated via digs or otherwise extends into an ILD underneath it, effectively stopping cracks traveling through the ILD-ILD interface (e.g., interface 410) from propagating into the active circuit area of chip 400.

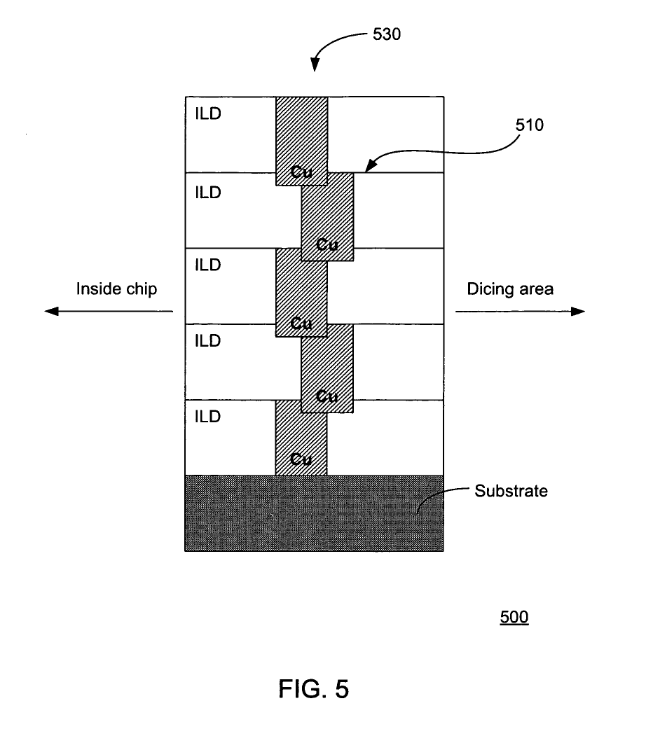

In some embodiments, the guard ring structure may comprise staggered metal bars that overlap horizontally as well as vertically. FIG. 5 is a cross sectional view of a schematic representation of a staggered guard ring structure 530 according to one embodiment of the invention As illustrated in FIG. 5, each metal bar of staggered guard ring structure 530 may extend into a portion of an ILD underneath it and a portion of another metal bar underneath it.

Portions of these staggered metal bars overlap horizontally as well as vertically, effectively stopping cracks from traveling through inter-layer interfaces (e.g., interface 510) from propagating into the active circuit area of chip 500.

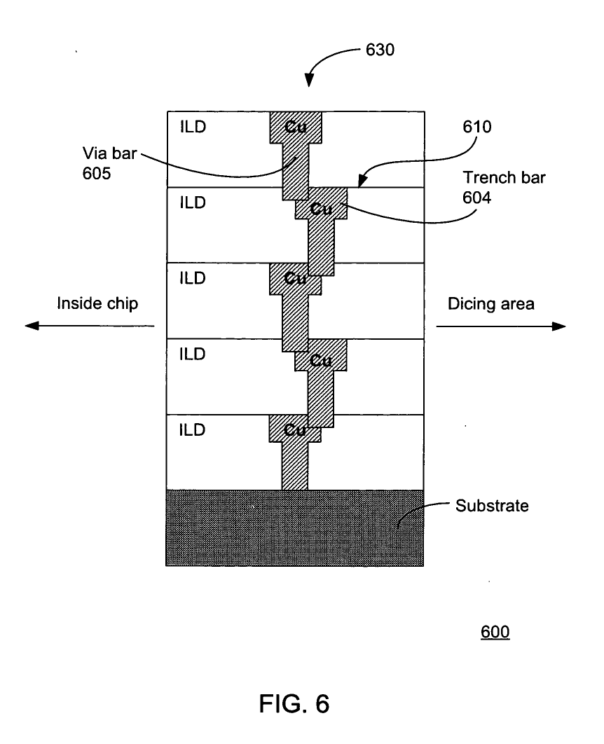

FIG. 6 is a cross sectional view of a schematic representation of a staggered guard ring structure according to another embodiment of the invention. Staggered guard ring structure 630 is similar to staggered guard ring structure 530 of FIG. 5 in that portions of the metal bars overlap in two planes. In this embodiment, wires are wider than vias. As illustrated in FIG. 6, the bottom part of a via (e.g., via bar 605) is extended and formed into a portion of an ILD underneath it and a portion of a wire (e.g., trench bar 604) underneath it. In this way, metal-metal interfaces (e.g., interface 620) do not exist on the same plane as ILD-ILD interfaces (e.g., interface 610) and any cracks propagating from the dicing area can be stopped by staggered guard ring structure 630 from affecting the circuit area of chip 600.

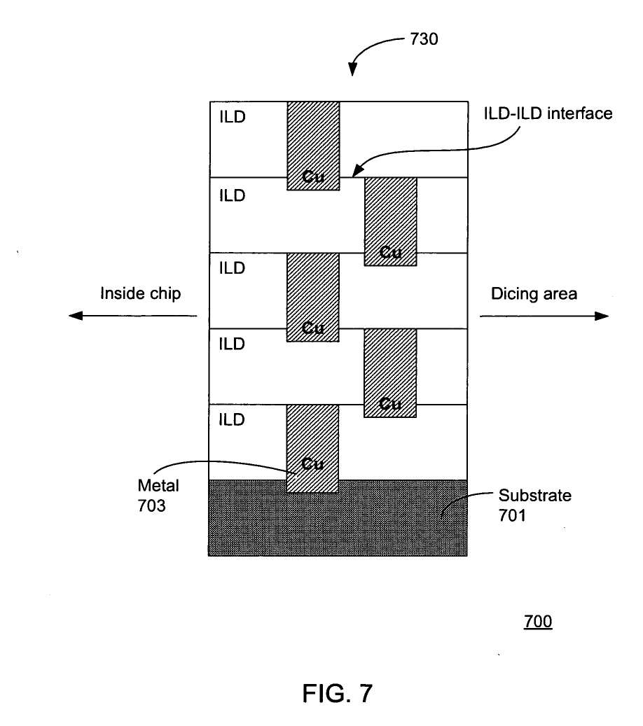

In some embodiments, the staggered guard ring structure may extend into a substrate. For example, in staggered guard ring structure 730 of FIG. 7, the bottom portion of metal bar 703 extends into substrate 701 of chip 700.

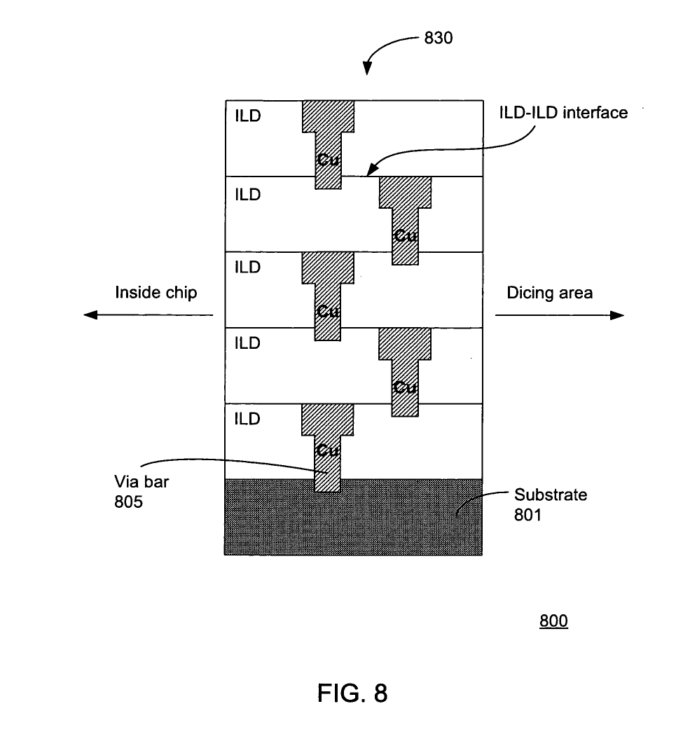

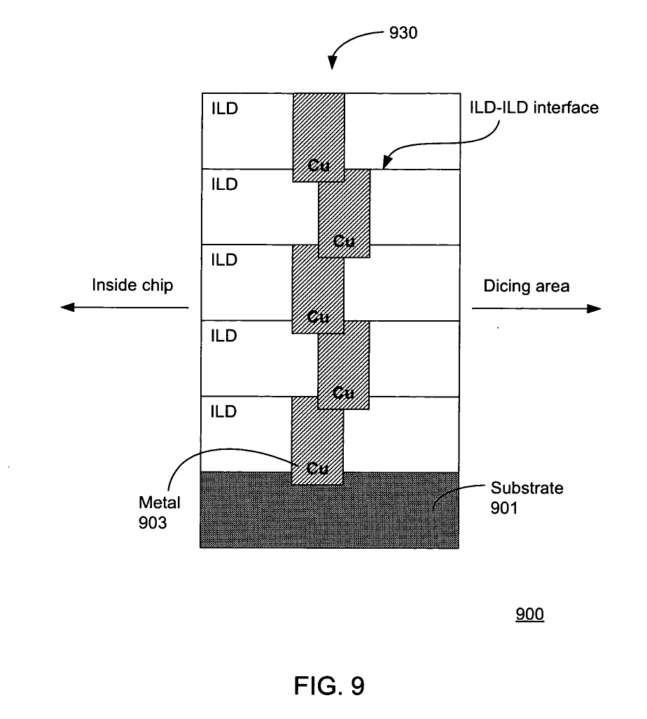

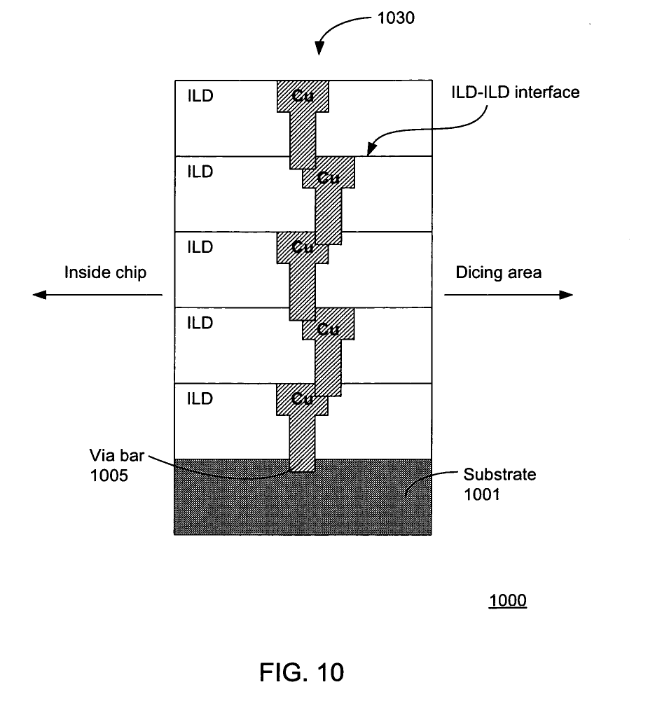

Staggered guard ring structure 730 is otherwise similar to staggered guard ring structure 330 of FIG. 3. In staggered guard ring structure 830 of FIG. 8, the bottom portion of via bar 805 extends into substrate 801 of chip 800. Staggered guard ring structure 830 is otherwise similar to staggered guard ring structure 430 of FIG. 4. In staggered guard ring structure 930 of FIG. 9, the bottom portion of metal bar 903 extends into substrate 901 of chip 900. Staggered guard ring structure 930 is otherwise similar to staggered guard ring structure 530 of FIG. 5. In staggered guard ring structure 1030 of FIG. 10, the bottom portion of via bar 1005 extends into substrate 1001 of chip 1000. Staggered guard ring structure 1030 is otherwise similar to staggered guard ring structure 630 of FIG. 6.

Although the present invention has been described in detail herein with reference to the illustrative embodiments, it should be understood that the description is by way of example only and is not to be construed in a limiting sense. It is to be further understood, therefore, that numerous changes in the details of the embodiments of this invention and additional embodiments of this invention will be apparent to, and may be made by, persons of ordinary skill in the art having reference to this description. Accordingly, the scope of the invention should be determined by the following claims and-their legal equivalents.

What is claimed is:

1. A staggered guard ring structure, comprising:
a plurality of metal bars positioned between a dicing area and an active circuit area of an integrated circuit (IC) chip,
wherein said plurality of metal bars are formed vertically on top of a substrate of said IC chip,
wherein each of said plurality of metal bars is formed into an inter-layer dielectric (ILD) of said chip, and
wherein each of said plurality of metal bar extends into an ILD underneath it.

2. The staggered guard ring structure of claim 1, wherein said plurality of metal bars are arranged in a staggered pattern, with a portion of a first metal bar overlapping a portion of a second metal bar.

3. The staggered guard ring structure of claim 2, wherein said first metal bar overlaps said second metal bar horizontally but not vertically.

4. The staggered guard ring structure of claim 3, wherein said plurality of metal bars has no metal-metal interfaces.

5. The staggered guard ring structure of claim 3, wherein said IC chip comprises a plurality of ILD-ILD interfaces, and wherein said plurality of metal bars has no metal-metal interfaces on same plane as said plurality of ILD-ILD interfaces, thereby stopping cracks from propagating from said dicing area through said plurality of ILD-ILD interfaces into said active circuit area of said chip.

6. The staggered guard ring structure of claim 3, wherein one of said plurality of metal bars extends into said substrate of said chip.

7. The staggered guard ring structure of claim 2, wherein said first metal bar overlaps said second metal bar horizontally and vertically.

8. The staggered guard ring structure of claim 7, wherein a first of said plurality of metal bars comprises a trench bar and an elongated via bar formed into a portion of an ILD underneath said first metal bar and a portion of a trench bar of a second metal bar underneath said elongated via bar.

9. The staggered guard ring structure of claim 7, wherein said IC chip comprises a plurality of ILD-ILD interfaces, and wherein said plurality of metal bars has no metal-metal interfaces on same plane as said plurality of ILD-ILD interfaces, thereby stopping cracks from propagating from said dicing area through said plurality of ILD-ILD interfaces into said active circuit area of said chip.

10. The staggered guard ring structure of claim 7, wherein one of said plurality of metal bars extends into said substrate of said chip.

11. The staggered guard ring structure of claim 1, wherein each of said plurality of metal bars comprises a via bar and a trench bar, and wherein said via bar and said trench bar have same or different dimensions.

12. The staggered guard ring structure of claim 1, wherein said plurality of metal bars comprise copper.

13. A staggered guard ring structure, comprising:
a plurality of metal bars positioned between a dicing area and an active circuit area of an integrated circuit (IC) chip,
wherein said plurality of metal bars are formed vertically on top of a substrate of said IC chip,
wherein each of said plurality of metal bars is formed into an inter-layer dielectric (ILD) of said chip,
wherein each of said plurality of metal bar extends into an ILD underneath it, and
wherein said plurality of metal bars are arranged in a staggered pattern, with a portion of a first metal bar overlapping a portion of a second metal bar horizontally but not vertically.

14. The staggered guard ring structure of claim 13, wherein said plurality of metal bars has no metal-metal interfaces.

15. The staggered guard ring structure of claim 3, wherein said IC chip comprises a plurality of ILD-ILD interfaces, and wherein said plurality of metal bars has no metal-metal interfaces on same plane as said plurality of ILD-ILD interfaces, thereby stopping cracks from propagating from said dicing area through said plurality of ILD-ILD interfaces into said active circuit area of said chip.

16. The staggered guard ring structure of claim 13, wherein one of said plurality of metal bars extends into said substrate of said chip.

17. A staggered guard ring structure, comprising:
a plurality of metal bars positioned between a dicing area and an active circuit area of an integrated circuit (IC) chip,
wherein said plurality of metal bars are formed vertically on top of a substrate of said IC chip,
wherein each of said plurality of metal bars is formed into an inter-layer dielectric (ILD) of said chip,
wherein each of said plurality of metal bar extends into an ILD underneath it, and
wherein said plurality of metal bars are arranged in a staggered pattern, with a portion of a first metal bar overlapping a portion of a second metal bar horizontally and vertically.

18. The staggered guard ring structure of claim 17, wherein a first of said plurality of metal bars comprises a trench bar and an elongated via bar formed into a portion of an ILD underneath said first metal bar and a portion of a trench bar of a second metal bar underneath said elongated via bar.

19. The staggered guard ring structure of claim 7, wherein said IC chip comprises a plurality of ILD-ILD interfaces, and wherein said plurality of metal bars has no metal-metal interfaces on same plane as said plurality of ILD-ILD interfaces, thereby stopping cracks from propagating from said dicing area through said plurality of ILD-ILD interfaces into said active circuit area of said chip.

20. The staggered guard ring structure of claim 7, wherein one of said plurality of metal bars extends into said substrate of said chip.
